(19) United States
(12) Patent Application Publication
(10) Pub. No.: US 2020/0165446 A1
(43) Pub. Date: May 28, 2020

(54) COMPOSITE MATERIAL MADE OF THERMOSETTING RESIN COMPOSITION

(71) Applicant: NAN YA PLASTICS CORPORATION, Taipei (TW)

(72) Inventors: Te-Chao LIAO, Taipei (TW); Ying-Te HUANG, Taipei (TW); Hao-Sheng CHEN, Taipei (TW); Hung-Yi CHANG, Taipei (TW); Chia-Lin LIU, Taipei (TW)

(21) Appl. No.: 16/202,156

(22) Filed: Nov. 28, 2018

(51) Int. Cl. C08L 71/12; C08L 47/00; C08L 53/02; H05K 1/03

(52) U.S. Cl. CPC C08L 71/12; C08L 47/00; C08L 53/02; H05K 1/0373; C08L 2205/025; H05K 2201/0158; C08L 2201/02; C08L 2312/00; C08L 2203/20; H05K 2201/0129; H05K 2201/012; C08L 2205/035

(57) ABSTRACT

A thermosetting resin composition comprises a thermosetting polybutadiene resin, a thermosetting polyphenylene ether resin that is ended with styrene and acrylate in a weight ratio of 0.5-1.5 as reactive functional groups, a thermoplastic resin that serves to set desired heat resistance, flowability and filling performance, a compound cross-linking initiator composed of peroxides of different half-life temperatures to effectively improve its crosslink density during its thermal curing process; particularly the composition after cured has a low dielectric constant, a low dielectric dissipation factor, a high Tg, and high rigidity, and the prepreg made thereof is easy to cut.

### BACKGROUND OF THE PRESENT INVENTION

### 1. Field of the Invention

The present invention relates a composite material made of a thermosetting resin composition.

### 2. Description of Related Art

Conventionally, the insulating materials used in printed circuit boards are mainly epoxy resins for they are good in terms of electric insulativity and chemical resistance after cured, and economically competitive. However, with the rapid development of high-frequency and broadband communication devices, signal velocity and data amount have been doubled. Meanwhile, electronic equipment and electronic packaging are becoming increasingly dense, and printed circuit boards are made to be thinner halogen-free trend while having smaller pitches and higher layer counts. In face of such a tendency, epoxy resins are becoming inadequate in terms of electrical property, water absorbency, flame resistance, and dimensional stability.

U.S. Pat. No. 5,223,568 discloses a moldable thermoplastic composition for use in circuit carriers, which is made by mixing a polybutadiene or polyisoprene resin which is a liquid at room temperature and which has a molecular weight less than 5,000 with a solid butadiene or isoprene-containing polymer (e.g., a thermoplastic elastomer). This known composition disadvantageously cures at high temperature (at a hot-press temperature higher than 250° C.), and the high viscidity of polybutadiene is unfavorable to automated continuous production of copper clad laminates. In addition, since polybutadiene is inflammable, greater addition of flame retardants is required for the composition to comply with UL-94V0.

Polyphenylene ether resins have outstanding electric insulativity, acid- and alkali-resistance, and good dielectric constants as well as dielectric dissipation factors, making them more suitable for insulation of circuit boards than epoxy resins in terms of electrical property. Nevertheless, the polyphenylene ether resins on the market are mostly thermoplastic and molecularly heavy (having a number-average molecular weight >20,000). They are less soluble in solvents, and thus are not readily applicable to manufacturing of circuit boards. For addressing the foregoing shortcomings, many attempts have been made by researchers to modify polyphenylene ether resins them into curable, more compatible and more processible resin materials while not sacrificing their excellent electrical properties.

U.S. Pat. No. 7,858,726 uses a redistribution reaction to convert a polyphenylene ether resin into its lower-molecular weight version. While the resulting resin has improved solubility, its molecular link is ended with hydroxyl groups, meaning that while it is curable, the polar groups can lead to greater dielectric dissipation. Besides, every polyphenylene ether molecule has only up to two hydroxyl groups, so there are not enough reactive radicals for proper curing and good crosslink density after curing. Once reactive radicals are inadequate for satisfying crosslink density, the product is less resistant to heat.

As mentioned in U.S. Pat. No. 7,141,627, while hydroxyl groups may act as reactive radicals, if there are quantitatively excessive hydroxyl groups not completely reacted during curing, the residual hydroxyl groups can make the resulting boards suffer to serious dielectric dissipation and high water absorbency. Thus, for materials need to have low dielectric constants and low dielectric dissipation factors, curing with hydroxyl groups is ineffective in endowing them with desired electrical properties and water absorbency.

In prior art, there is a modified polyphenylene ether resin ended with unsaturated groups. When co-cured with bismaleimide, its gel time can be shortened. According to one embodiment, use of a styrene-based polyphenylene ether leads to improved heat resistance. However, since styrene groups are rigid, the resin is less flowable during thermal curing. In addition, bismaleimide is less soluble, and tends to separate during processing, leading to problems concerning dispersion.

There is another known resin composition using polyphenylene ether that has OH groups and methyl methacrylate as well as acrylate groups at its ends. Since polyphenylene ether ended with OH groups often has higher polarity and in turn higher water absorbency, its electrical properties are adverse affected. On the other hand, while acrylate groups can provide a soft structure that contributes to better flowability during curing, they are not helpful to desired heat resistance, flame resistance, and mechanical strength. For example, China Patent No. CN103834132 discloses a halogen-free retardant acrylic resin designed to have enhanced flame resistance.

In the prior art, as reported in U.S. Pat. No. 5,223,568, a polybutadiene resin is used for desired electrical properties. However, since its molecular structure is based on carbon-hydrogen bonds, its Tg is lower than the room temperature, making it tend to stick. Control of its processing is relatively difficult, and there are likely processability-related issues, such as sticky prepreg and uneven thickness.

Although processability can be improved by increasing baking temperature and time, this solution can often degrade the entire varnish's reactivity and the laminates' physical properties, and in turn the prepreg's flowability, leading to poor filling performance, making the product unusable.

Additionally, the polybutadiene resin is structurally weak in terms of flame resistance, making significant addition of and flame retardants necessary, yet such addition can adversely affects other important physical properties, leading to low heat resistance, low glass transition temperature (Tg), and high electrical properties.

As compared to polybutadiene resins, polyphenylene ether structurally has more benzene rings, so is more stable. Its prepreg shows good processability, and is not sticky on hands as its Tg is higher than the room temperature. While it is more resistant to flame resistance, it is inferior to polybutadiene resins in terms of electrical property.

Additionally, engineering plastic-grade polyphenylene ether resins on the market are molecularly-weight too heavy and less soluble, bringing adverse effects on the addition level and the overall properties.

On the other hand, use of low-molecular-weight polyphenylene ether resins is helpful to improve solubility (as stated in U.S. Pat. No. 7,858,726), yet it degrades the resulting heat resistance. If a low-molecular-weight polyphenylene ether resin is modified into a thermosetting polyphenylene ether resin ended with specific functional groups, its crosslink density and heat resistance after thermal curing can be improved, making it more applicable.

Although use of hydroxyl groups as the end groups of a thermosetting polyphenylene ether resin is feasible, this can disadvantageously lead to generation of polar groups during curing, and in turn adversely affect the cured board in terms of dielectric constant and dielectric dissipation factor. Additionally, the resulting high water absorbency can cause delamination and low heat resistance (as stated in U.S. Pat. No. 7,141,627).

When a thermosetting polyphenylene ether resin having been modified to be ended with non-polar groups (such as unsaturated groups like alkenyl groups and alkynyl groups) undergoes thermal curing, there are no polar groups generated during curing and no polar groups remained after curing. This ensures its lower Dk and Df values, as well as lower water absorbency.

When a thermosetting polyphenylene ether resin having been further modified to be ended with acrylate groups or styrene groups (both being non-polar groups) undergoes thermal curing, there are no polar groups generated during curing, leading to even better electrical properties and lower water absorbency.

Acrylate groups are of a carbon-hydrogen bond structure and structurally soft, so display good flowability in the thermal curing process. However, since carbon-hydrogen bonds are less stable and subject to pyrolysis under heat, the resulting resin is less heat-resistant.

Styrene groups have benzene rings and are structurally rigid. Thanks to electron resonance, the resulting resin has stable structure and is heat-resistant. However, it is less flowable in the process of thermal curing. Particularly, when applied to thick copper (2 OZ or more) lamination process, the poor flowability can lead to poor filling performance.

### BRIEF SUMMARY OF THE INVENTION

To address the problems of the prior art, there is a need for a thermosetting resin composition that provides more non-polar unsaturated functional groups, and can be made with proper processability and flowability. The thermosetting resin composition comprises a thermosetting polyphenylene ether resin, a thermosetting polybutadiene resin, and a thermoplastic resin.

One objective of the present invention is to provide a thermosetting resin composition made of a thermosetting polyphenylene ether resin, a thermosetting polybutadiene resin, and a thermoplastic resin in a proper ratio. The composition advantageously has low dielectric properties and good flowability/processability.

Another objective of the present invention is to provide a thermosetting polyphenylene ether resin, which has a curable, unsaturated, reactive functional group in its backbone chain and contains no polar groups. The resin features significantly lowered Dk and Df values as well as lowered water absorbency.

Another objective of the present invention is to provide a thermosetting resin composition, which comprises a thermosetting polybutadiene resin containing a polybutadiene resin or a butadiene-styrene copolymer, in which the polybutadiene resin has a number-average molecular weight (Mn) of smaller than 5,000 for good flowability. The butadiene-styrene copolymer has styrene groups in a proportion of 10-35% for showing good reactivity and flowability while keeping its dielectric properties low.

Another objective of the present invention is to provide a thermosetting resin composition, which contains a certain proportion of a thermoplastic resin, including one or more of polystyrene and a styrene-containing copolymer, for setting the flowability and processability of the entire resin composition. Particularly, the thermoplastic resin has low dielectric properties and its addition does not cause deviation of dielectric properties.

The thermoplastic resin of the present invention is one or a combination of any selected from a polystyrene-poly(ethylene-ethylene/propylene)-polystyrene resin (SEEPS), a polystyrene-poly(ethylene-propylene)-polystyrene resin (SEPS), a polystyrene-poly(ethylene-butylene)-polystyrene resin (SEBS), and a polystyrene resin (PS), wherein the styrene-containing copolymer contains styrene groups in a proportion of 10-85%.

Another objective of the present invention is to provide a thermosetting resin composition, which is mainly based on a thermosetting polyphenylene ether resin and contains a styrene-based polyphenylene ether resin and an acrylate-based polyphenylene ether resin. The styrene-based polyphenylene ether resin and the acrylate-based polyphenylene ether resin exist with a certain ratio therebetween so as to improve the acrylate-based structure for good heat resistance, and improve the styrene-based structure for good flowability.

Another objective of the present invention is to provide a thermosetting polyphenylene ether resin that has a proper molecular weight and good processability, while being soluble to solvents and well compatible to epoxy resins.

Another objective of the present invention is to provide a thermosetting resin composition having the foregoing advantages. The thermosetting resin composition comprises:
(a) a thermosetting polyphenylene ether resin, taking up 10-30 wt % of the total solid content of the resin composition, which includes a styrene-based polyphenylene ether resin and an acrylate-based polyphenylene ether resin, wherein the ratio of the styrene-based polyphenylene ether resin to the acrylate-based polyphenylene ether resin is 0.5-1.5;
(b) a thermosetting polybutadiene resin, taking up 10-30 wt % of the total solid content of the resin composition;
(c) thermoplastic resin, taking up 10-30 wt % of the total solid content of the resin composition;
(d) inorganic powder (a filler), taking up 20-40 wt % of the total solid content of the resin composition
(e) a flame retardant, taking up 5-25 wt % of the total solid content of the resin composition;
(f) a cross-linking agent, taking up 5-20 wt % of the total solid content of the resin composition; and
(g) a compound cross-linking initiator, taking up 0.1-3 wt % of the total solid content of the resin composition.

Apart from the foregoing improvements in physical properties, the present invention also improves substrate processability, including low-temperature lamination and prepreg cutability. Copper clad laminates made of the cured thermosetting resin composition has good rigidity, and the prepreg is not too soft to be cut easily, meaning that there is no need to frequently change tools during production, saving relevant costs and making it perfect for printed circuit boards in multi-layer applications, such as servers.

Another objective of the present invention is to apply the aforementioned resin composition to semi-cured prepreg and cured prepreg for printed circuit boards, copper clad laminates made by laminating impregnated glass cloth and copper foil, and circuit boards made of such copper clad laminates. Since the composition contains the aforementioned thermosetting polyphenylene ether resin and thermosetting polybutadiene resin, and has a certain proportion of a thermoplastic resin that contains one or more of polystyrene and a copolymer having styrene groups, it after cured has a low dielectric constant, a low dielectric dissipation factor, a high Tg, high heat resistance, and high flame resistance, and is highly soluble to solvents, while very compatible to other resins.

The product inherits the benefits of the thermosetting resin composition and supports to better PCB specifications. The cured composition advantageously has a dielectric constant (Dk) smaller than 3.0 and a dielectric dissipation factor (DO small than 0.0017 at 1GHz, and has a glass transition temperature (Tg) higher than 210° C., while its 288° C. soldering heat resistance is more than 600 seconds.

### DETAILED DESCRIPTION OF THE INVENTION

For further illustrating the means and functions by which the present invention achieves the certain objectives, the following description is set forth as below to illustrate the implement, structure, features and effects of the subject matter of the present invention. It is understood that the embodiments are not intended to limit the scope of the present invention.

The thermosetting polyphenylene ether resin of the present invention is a composition containing a styrene-ended polyphenylene ether and an acrylate-ended polyphenylene ether.

The styrene-ended polyphenylene ether has a structure as expressed by Formula (A) as follows:

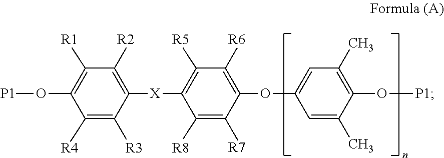

where R1-R8 may be allyl or hydryl or C1-C6 alkyl, or one or more selected from the foregoing group,
X may be O (oxygen atoms), or

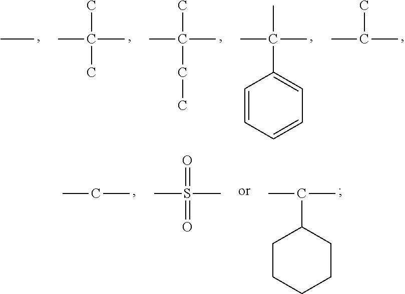

where P1 is a styrene group or

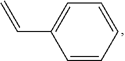

n is an integer in a range of 1-99.

The acrylate-ended polyphenylene ether has a structure as expressed by Formula (B) as follows:

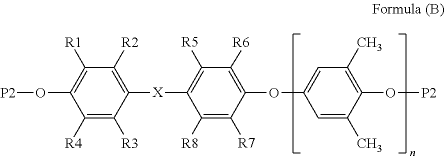

where R1-R8 may be allyl or hydryl or C1-C6 alkyl, or one or more selected from the foregoing group.
X may be: O (oxygen atoms), or

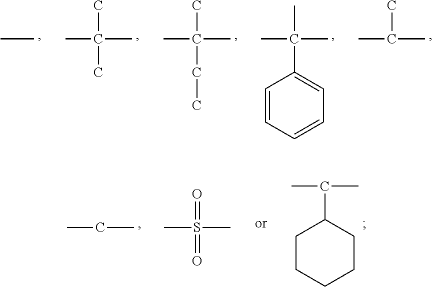

### P2 is

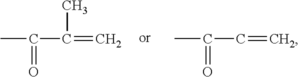

n is an integer in a range of 1-99.

The disclosed thermosetting polyphenylene ether resin may be made in at least two ways. The first is oxidative polymerization, where carbon and oxygen atoms (C—O) are oxidatively polymerized by reacting 2,6-dimethyl Phenol (2,6-DMP) and oxygen (O2) or air with the presence of a coordination complex catalyst made of an organic solvent, copper and amines. Moreover, 2,6-DMP may be co-polymerized with a phenol containing functional groups and modified. The polyphenylene ether resin obtained through oxidative polymerization still has a certain amount of hydroxyl groups at the ends of its molecular chain, making it possible to be provided with different reactive functional groups through further end-graft reaction.

The second involves using pyrolysis reaction between phenols and peroxides to convert a polyphenylene ether resin containing no functional groups into one with lower molecular weight. The polyphenylene ether resin obtained through pyrolysis still has a certain amount of hydroxyl groups at the ends of its molecular chain, making it possible to be provided with different reactive functional groups through further end-graft reaction. Alternatively, diphenols having different functional groups may be used to provide the low-molecular-weight polyphenylene ether with different reactive functional groups.

According to the present invention, the thermosetting polyphenylene ether resin is made by further performing grafting modification on the hydroxyl groups ending the molecular chain of the polyphenylene ether resin. The graft reaction is based on the principle of nucleophilic substitution. To do this, the end hydroxyl groups of the low-molecular-weight polyphenylene ether resin are first sodium-salinized or potassium-salinized to form end phenoxide.

The end phenoxide is highly reactive, and can react with monomers like halides, acid halides, and acid anhydrides. During reaction, an acid monomer such as halides, acid halides, and acid anhydrides containing unsaturated reactive radicals (such as alkenyl groups and alkynyl groups) is introduced as an end-capping/grafting monomer with the presence of a phase-transfer catalyst. After graft reaction, the residues of the monomer connect with the oxygen atoms of the polyphenylene ether backbone chain to form the disclosed thermosetting polyphenylene ether resin.

Another objective of the present invention is to provide a thermosetting resin composition having the foregoing benefits. The disclosed resin composition refers to a composition using the aforementioned thermosetting polyphenylene ether resin. The composition comprises: (a) a thermosetting polyphenylene ether resin, taking up 10-30 wt % of the total solid content of the resin composition, and including a styrene-based polyphenylene ether resin and an acrylate-based polyphenylene ether resin, where the ratio of the styrene-based polyphenylene ether resin to the acrylate-based polyphenylene ether resin is of 0.5-1.5, (b) a thermosetting polybutadiene resin, taking up 10-30 wt % of the total solid content of the resin composition, (c) a thermoplastic resin, being one or a combination of polystyrene and a styrene-based butadiene copolymer, taking up 10-30 wt % of the total solid content of the resin composition, (d) inorganic powder, taking up 20-40 wt % of the total solid content of the resin composition, (c) a flame retardant, taking up 5-25 wt % of the total solid content of the resin composition, (d) a cross-linking agent, taking up 5-20 wt % of the total solid content of the resin composition, and (e) a compound cross-linking initiator, being an organic peroxide containing more than 5% of reactive oxygen, taking up 0.1-3 wt % of the total solid content of the resin composition. The functions, proportions and structures of the components are detailed below:
(a) The thermosetting polyphenylene ether resin takes up 10-30 wt % of the total solid content of the resin composition, and contains a styrene-based polyphenylene ether resin of Formula (A) and an acrylate-based polyphenylene ether resin of Formula (B) as follows:

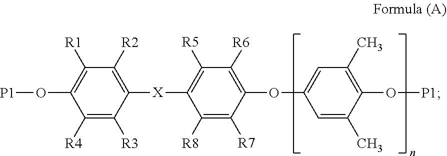

where R1-R8 may be allyl or hydryl or C1-C6 alkyl, or one or more selected from the foregoing group,
X may be O (oxygen atoms), or

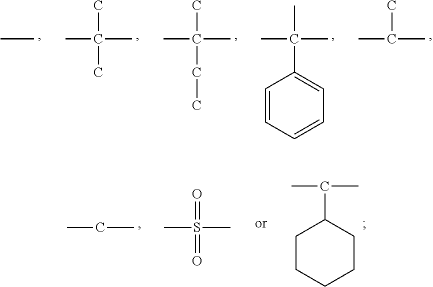

where P1 is a styrene group, n is an integer in a range of 1-99.

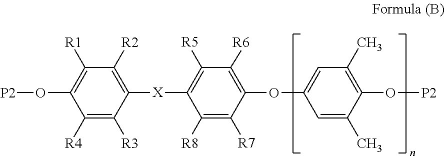

where R1-R8 may be allyl or hydryl or C1-C6 alkyl, or one or more selected from the foregoing group.
X may be: O (oxygen atoms), or

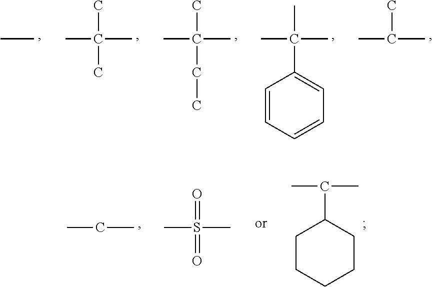

### P2 is

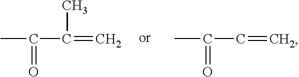

n is an integer in a range of 1-99.

In the present invention, the thermosetting polyphenylene ether resin includes a styrene-ended polyphenylene ether resin and an acrylate-ended polyphenylene ether resin, wherein the ratio of the styrene-containing polyphenylene ether resin to the acrylate-containing polyphenylene ether resin of 0.5-1.5, and preferably of 0.75-1.25.

In the present invention, the thermosetting polyphenylene ether resin preferably has a number-average molecular weight (Mn) ranging between 1,000 and 25,000, and more preferably ranging between 2,000 and 10,000 for better physical properties, such as glass transition temperature (Tg), dielectric constant, and dielectric dissipation factor.

In the present invention, the thermosetting polyphenylene ether resin is ended with at least one unsaturated active functional group. The number of the end-grafting functional groups is determined by measuring the OH value. To measure the OH value, a 25 vol. % acetic anhydride solution in pyridine is prepared as an acetylation reagent. A few grams of the sample to be tested is precisely weighted and well mixed with 5 mL of the acetylation reagent. After heated to full dissolution, the mixture is added with penolphthalein as the indicator. A 0.5 N potassium hydroxide solution in ethanol is used for standardization.

The thermosetting polyphenylene ether resin used in the present invention preferably has an OH value of smaller than 2.0 mgKOH/g, more preferably smaller than 1.0 mgKOH/g, and may be down to 0.001 mgKOH/g to ensure there are enough functional groups for reaction, thereby ensure desired physical properties, such as: glass transition temperature (Tg) and heat resistance. Where the OH value is greater than 10.0 mgKOH/g, there are not enough end-grafting functional groups. This leads to not only unsatisfying physical properties (Tg or heat resistance) of the cured resin, but also delaminated laminates.

The thermosetting polyphenylene ether resin used in the present invention is preferably to have a minimal OH value, which means the polyphenylene ether resin in the formula provides enough functional groups required by reaction. In this case, the laminating temperature of the composition can be kept as low as 150-200° C. while contributing to the desired physical properties.
(b) The thermosetting polybutadiene resin includes a polybutadiene resin or a butadiene-styrene copolymer. The polybutadiene resin must have a number-average molecular weight (Mn) of smaller than 5,000 for good flowability. The butadiene-styrene copolymer contains styrene groups in a proportion of 10-35%. The resin advantageously has not only good reactivity and flowability, but also low dielectric properties.
(c) The thermoplastic resin is a polystyrene resin, a styrene-containing copolymer, or a combination thereof, and may be one or more selected from polystyrene-poly(ethylene-ethylene/propylene)-polystyrene resin (SEEPS), polystyrene-poly(ethylene-propylene)-polystyrene resin (SEPS), polystyrene-poly(ethylene-butylene)-polystyrene resin (SEBS), and polystyrene resin (PS).
   In the present invention, the thermoplastic resin does not have any reactive alkenyl groups, but contains a certain proportion of styrene groups, so as to prevent problems about softness due to only having hydrocarbon chains and have better processability.

The styrene-containing copolymer of the thermoplastic resin is preferably a copolymer containing styrene groups of a proportion of 10-85%, and more preferably 20-60%.

The thermoplastic resin of the present invention no more contains reactive alkenyl groups and is thus unable to crosslink with the thermosetting resin during curing. Therefore, when added in the resin composition, it helps to enhance flowability and adhesion to copper foil. Furthermore, the added thermoplastic resin can form a SEMI-IPN polymer with the thermosetting resin, further enhancing toughness and mechanical strength of the cured resin composition.

Since the thermoplastic resin is not recurable, there is an optimal addition proportion. A preferred addition proportion is 10-30% (percentage by weight). An addition level lower than 10% is no use to enhance flowability and toughness. On the other hand, an addition level greater than 30% can lower Tg and heat resistance of the resulting substrate.
(d) The inorganic powder takes up 20-40 wt % of the total solid content of the resin composition. Its purpose is to improve the cured resin composition in terms of mechanical strength and dimensional stability. The inorganic powder is one or more selected from spherical or irregular SiO₂, TiO₂, Al(OH)₃, Al₂O₃, Mg(OH)₂), MgO, CaCO₃, B₂O₃, CaO, SrTiO₃, BaTiO₃, CaTiO₃, 2MgO.TiO₂, CeO₂, fume silica, BN, and AlN. The inorganic powder preferably has an average particle size of 0.01-20 μm. Therein, smoked silica is in the form of porous nano-sized silica particles with an average particle size of 1-100 nm and has an addition proportion of 0.1-10 wt %. If smoked silica is added with an addition proportion greater than 10 wt %, the resulting resin composition can be too sticky to be easily processed. Therein, the used silicon dioxide may be fused or crystalline silicon dioxide. For better dielectric properties of the composition, fused silicon dioxide is more preferable, such as 525ARI from Sibelco Bao Lin.
(e) The flame retardant takes up 5-25 wt % of the total solid content of the resin composition. It may be a brominated and phosphorus flame retardant. Suitable brominated flame retardants include Saytex BT 93W (an ethylene bistetrabromophthalimide flame retardant), Saytex BT93, Saytex 120 (a tetradecabromodiphenoxy benzene flame retardant), Saytex 8010 (an ethane-1,2-bis(pentabromophenyl) flame retardant) or an Saytex 102 (a decabromo diphenoxy oxide flame retardant), all made by Albemarle Corporation (a US-based company).

The phosphorus flame retardant may be a phosphate-based one, such as triphenyl phosphate (TPP); resorcinol bis(diphenyl phosphate) (RDP); bisphenol A bis(diphenyl)phosphonate (BPAPP); bisphenol A bis(dimethyl)phosphonate (BBC); resorcinol bis(diphenylphosphate) (CR-733S); and tetrakis(2,6-dimethylphenyl) 1,3-phenylene bisphosphate (PX-200); a phosphazene-based one, such as: poly(diphenoxy)phosphazene (SPB-100); ammonium polyphosphate, melamine polyphosphate (MPP), melamine cyanurates; and a DOPO-based flame retardant, such as DOPO (referred to Formula C), DOPO-HQ (referred to Formula D), dual-DOPO derivatives (referred to Formula E); Al-containing hypophosphites (referred to Formula F).

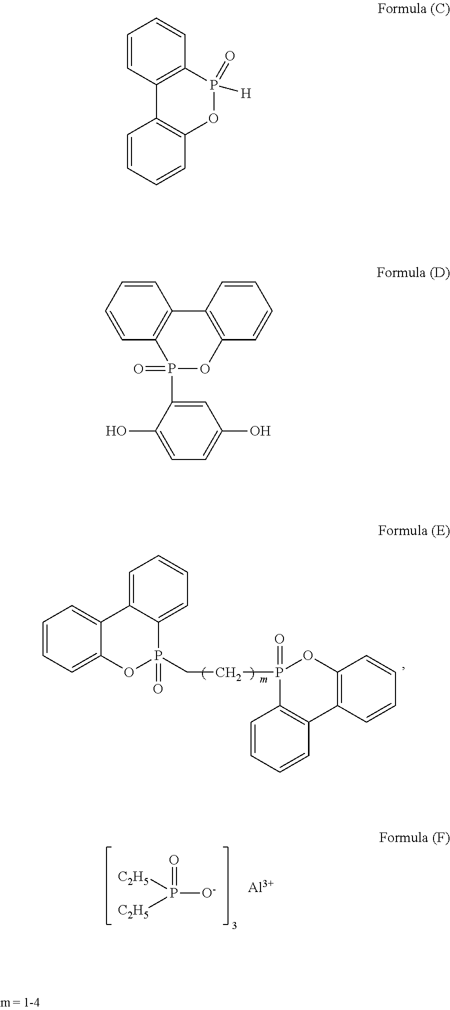

The flame retardant may be one or a combination of any of the foregoing group. When added in the polyphenylene ether resin, a brominated flame retardant has a glass transition temperature higher than that of a phosphorus flame retardant.
(f) The cross-linking agent takes up 5-20 wt % of the total solid content of the resin composition. It serves to increase the crosslink density of the thermosetting resin and to endow the substrate with proper rigidity, toughness and processability. It may be one or a combination of any of triallyl cyanurate (TAC); triallyl isocyanurate (TAIC); trimethallyl isocyanurate (TMAIC); diallyl phthalate; divinylbenzene; and 1,2,4-triallyl trimellitate.
(g) The compound cross-linking initiator is typically an organic peroxide, taking up 0.1-3 wt % of the total solid content of the resin composition. It serves to accelerate cross-linking reaction at different temperatures. When the disclosed resin composition is heated to a specific temperature, the initiator is decomposed to release free radicals, which trigger crosslink polymerization. As the temperature increases, consumption of the peroxide increases.

Therefore, the peroxide and the resin composition have to match well. If the peroxide has its decomposition temperature lower than the activation energy of the polymerization, the resulting crosslink density may be too low.

The disclosed thermosetting resin composition uses a styrene-based polyphenylene ether resin and an acrylate-based polyphenylene ether resin mixed in a certain proportion. Styrene groups and acrylate groups are different in terms of activation energy, so a compound cross-linking initiator is needed to initiate the reaction and achieve the optimal physical properties. The initiator is prepared depending on the proportion of the two resins for the best crosslink density.

The used initiator is typically an organic peroxide, such as tert-butyl isopropylphenyl peroxide; dicumyl peroxide (DCP); benzoyl peroxide (BPO); 2,5-dimethyl-2,5-di(tert-butylperoxy)hexane; 2,5 -dimethyl-2,5 -di(tert-butylperoxy) hexyne; 1,1-di-(tert-butylperoxy)-3,3,5 -trimethylcyclohexane; or cumene hydroperoxide.

Herein, the compound cross-linking initiator is preferably an organic peroxide that contains more than 5% reactive oxygen.

Herein, the compound cross-linking initiator refers to a mixture of multiple cross-linking initiators based on the 1-hour half-life temperature of the peroxide, so that the compound cross-linking initiator can initiate multiple crosslink reaction at different temperatures throughout the heating/curing process of the disclosed thermosetting resin composition, thereby ensuring more complete crosslink of the resin composition, thereby achieving better heat resistance and physical properties.

The disclosed compound cross-linking initiator may be any combination of dicumyl peroxide (reactive oxygen: 5.86%, 1-hour half-life temperature: 137° C.), bis(tert-butyldioxyisopropyl)benzene (reactive oxygen: 9.17%, 1-hour half-life temperature: 139° C.), 2,5-dimethyl-2,5-di(tert-butylperoxy)hexane(reactive oxygen: 10.25%, 1-hour half-life temperature: 140° C.), di-tert-pentyl peroxide (reactive oxygen: 8.81%, 1-hour half-life temperature: 143° C.), di-tert-butyl peroxide (reactive oxygen: 10.78%, 1-hour half-life temperature: 149° C.), and cumene hydroperoxide (reactive oxygen: 9.14%, 1-hour half-life temperature: 188° C.). Therein, one preferable combination is of bis(tert-butyldioxyisopropyl) benzene and cumene hydroperoxide, with its use amount depending on the mixing proportion of the resin to have a cured product with the best physical properties, such as glass transition temperature and rigidity.

In addition, the disclosed resin mixture may be improved in terms of interface compatibility between inorganic powder resins by added a coupling agent. The coupling agent may be directly added into the resin mixture, or may be used to treat the inorganic powder before the latter is used to prepare the resin mixture of the present invention.

The subject of the present invention may be in the form of the thermosetting resin composition, prepreg made thereof, and its cured product. Therein, the prepreg is a composite material made by impregnating a reinforcement in the resin mixture at 15-40° C. and baked at 100-140° C. to dry.

In the present invention, the prepreg comprises the reinforcement of 10-50 wt % and the impregnation resin mixture of 50-90 wt %. Therein, the reinforcement is selected from glass cloth, non-woven glass cloth, organic fiber cloth, non-woven organic fiber cloth, paper, non-woven liquid crystal polymer cloth, synthetic fiber cloth, carbon fiber cloth, PP cloth, PTFE cloth and non-woven cloth.

The aforementioned prepreg composition is semi-cured prepreg and cured prepreg for printed circuit boards, copper clad laminates made by laminating impregnated glass cloth and copper foil, or printed circuit boards made of the copper clad laminates. Since the composition contains the aforementioned thermosetting polyphenylene ether resin, it has a low dielectric constant, a low dielectric dissipation factor, a high Tg, high heat resistance, and high flame resistance after cured, inheriting the benefits of the thermosetting polyphenylene ether resin, making it perfect for products of high-end PCB specifications.

The cured product of the prepreg after laminated with copper foil from above and below can form a copper clad laminate, suitable for high-frequency circuit substrates. The copper clad laminate may be manufactured by means of automated continuous production, where sheets of the prepreg are stacked and the stack is topped and bottomed by a respective sheet of 35 μm copper foil. The stack is pressed at 25 kg/cm2, 85° C. for 20 minutes. The temperature is increased to 150° C.-190° C. at a rate of 3° C./min and held for 120 minutes before decreased to 130° C. slowly, so as to get a copper clad laminate having a thickness of more than 0.8 mm

With the aforementioned thermosetting polyphenylene ether resin in its composition, the cured copper clad laminate has a low dielectric constant, a low dielectric dissipation factor, a high Tg, high heat resistance, high flame resistance, and low water absorbency, inheriting the benefits of the thermosetting polyphenylene ether resin, making it perfect for products of high-end PCB specifications.

The following embodiments and comparative embodiments are described for manifesting the effects of the disclosure and not intended to limit the present invention.

In various embodiment and comparative embodiments, copper clad laminates were made and tested for physical properties using the following protocols:
1. Glass Transition temperature (° C.):

Measured is used with a dynamic mechanical analyzer (DMA).
2. Water Absorbency (%):

Determined by heating test pieces in a pressure pot at 120° C. and 2 atm for 120 minutes and calculating the weight difference before and after the heating.
3. 288° C. Soldering Heat Resistance (sec):

Measured as the time taken before delamination occurred by heating test pieces in a pressure pot at 120° C. and 2atm for 120 minutes an and dipping them into a 288° C. soldering machine.
4. Copper Peel Strength (lb/in):

Measured as the peel strength between the copper foil and the circuit carrier.
5. Dielectric Constant Dk (1 GHz):

Measured at 3G Hz using a dielectric analyzer HP Agilent E4991A.
6. Dielectric Dissipation Factor Df (1 GHz):

Measured at 1G Hz using a dielectric analyzer HP Agilent E4991A.
7. Molecular Weight of the Polyphenylene Ether Resin:

Determined by dissolving a given amount of the polyphenylene ether resin in THF solvent to prepare a 1% solution, heating the solution to clearness, performing GPC (gel permeation chromatography) analysis and calculating the area of the characteristic peak.

The calibration curve for analysis was established using multiple polystyrene standards of different molecular weights for standardization. The established calibration curve was used to determine the molecular weight of the tested products.
8. OH Value:

Measured by preparing a 25 vol. % acetic anhydride solution in pyridine as the acetylation reagent, precisely weighting the sample, mixing it with 5 mL of the macetylation reagent, heating to full dissolution, adding phenolphthalein as the indicator, and standardizing using 0.5 N potassium hydroxide solution in ethanol.
9. Rigidity:

Measured using a dynamic mechanical analyzer (DMA), and expressed in the G′ value (storage modulus, GPa) at 50° C.

### Embodiments 1-11 and Comparative Embodiments 1-3

The resin compositions shown in Table 1 were made into varnishes of the thermosetting resin compositions using toluene. Nan Ya glass fiber cloth (Nan Ya Plastics Corporation, Model No. 7628) was impregnated with the varnishes at room temperature, and dried at 110° C. (in a dipping machine) for a few minutes, so as to get prepreg containing the resin of 43 wt %. Four sheets of the prepreg were stacked and sandwiched by two sheets of 35 μm copper foil. The sandwich was held at 85° C. and 25 kg/cm² for 20 minutes, and heated in a rate of 3° C./min until 185° C. The temperature was held for 120 minutes before decreased to 130° C. slowly to get a 0.8 mm copper clad laminate.

The copper clad laminates so made were tested for physical properties, and the results are detailed in Table 1.

### RESULTS AND CONCLUSIONS

By comparing the results of Embodiments 1-11 and Comparative Embodiments 1-3 as provided in Table 1, the following facts were concluded:
1. The circuit substrates of Embodiments 1-11 all performed well in terms of Dk and Df. The dielectric constant were all smaller than 3.0, and the dielectric dissipation factor were all smaller than 0.0017, while the glass transition temperature (Tg) were all higher than 200° C. As to other physical properties, such as copper peel strength, water absorbency, 288° C. soldering heat resistance, and flame resistance, all of them performed well. Particularly advantageous was that the prepreg was easy to cut and not sticky on hands.
2. The composition of Comparative Embodiment 1 using an acrylate-ended polyphenylene ether had lower rigidity and a lower Tg. It was slightly less resistant to heat, but the filling performance was fine. In Comparative Embodiment 2, styrene-ended polyphenylene ether used contributed to good substrate physical properties, bur the filling performance was not good. This is due to the end-group structure. Acrylate groups are soft, and are less resistant to heat but provide good flowability. Styrene groups are structurally stable and rigid, making the resin highly resistant to heat but less flowable.
3. Embodiments 1 and 2 each used an acrylate-ended polyphenylene ether and a styrene-ended polyphenylene ether resin in a ratio of 1:1, together with a thermosetting polybutadiene resin not containing a styrene group, plus a compound cross-linking initiator, and respectively used 20%-styrene SEBS and 100%-styrene PS as the thermoplastic resin. The one using SEBS had a lower Tg, but had better copper peel strength. The composition was competent in terms of line filling and heat resistance, and the prepreg was not sticky on hands.
4. In each of Embodiments 1, 2, 3, 4, 5, 10 and 11, the composition was made using a styrene-containing thermosetting polybutadiene resin together with a combination of acrylate-containing polyphenylene ether and a styrene-containing polyphenylene ether (1:1), plus a compound cross-linking initiator. The products were competent in terms of heat resistance, electrical property, and line filling. The electrical properties were even lower, with the Df up to 0.0015 and higher Tg.
5. In Embodiment 6, the composition was made using a phosphorus flame retardant of a DOPO structure and a styrene-containing thermosetting polybutadiene resin, together with a combination of a polyphenylene ether having acrylate groups and a polyphenylene ether having styrene groups (1:1), plus a compound cross-linking initiator. The product was competent in terms of heat resistance, electrical property, and line filling. Its Tg was not high, but still higher than 200° C.
6. Embodiment 7 increased the amount of the thermoplastic resin. The resulting Tg was not high, but still greater than 200° C. The rigidity and water absorbency were both slightly lowered.
7. Embodiments 8 and 9 used different brominated flame retardants, but both were competent in terms of heat resistance, electrical property, and line filling.
8. Comparative Embodiment 1 used the polyphenylene ether resin ended with OH groups. Since the ends contained no functional groups, the OH value was as high as 47 mgKOH/g, making the cured product have a low glass transition temperature (Tg) and poor heat resistance. The resulting substrate had inferior peel strength, a low and dielectric constant, and a high dielectric dissipation factor (Df=0.0037).
9. In Comparative Embodiment 2, the raised ratio of the thermosetting polybutadiene resin contributed to the lower dielectric constant and dielectric dissipation factor, but since polybutadiene resins are less heat resistant and inflammable, the prepreg had poor flame resistance and was sticky on hands.
10. In Comparative Embodiment 3, the raised ratio of the thermoplastic resin led to lower Tg, resulting in poor heat resistance NG.

TABLE 1
Prepreg Formula and Substrate Physical Property

| | | Embodiment | | | | | | |
|---|---|---|---|---|---|---|---|---|
| Composition (weight percentage) | | 1 | 2 | 3 | 4 | 5 | 6 | 7 |
| Thermosetting | PPE-A (ended with styrene groups) *¹ | 15 | 15 | 15 | 15 | 15 | 15 | 10 |
| polyphenylene | PPE-B (ended with | 15 | 15 | 15 | 15 | 15 | 15 | 10 |
| ether resin ¹ | acrylate groups) *² | | | | | | | |
| | PPE-C (ended with | — | — | — | — | — | — | — |
| | OH groups) | | | | | | | |
| | OH Value *³ | 0.01 | 0.02 | 0.02 | 0.02 | 0.02 | 0.02 | 0.02 |
| | Polyphenylene Ether | 2369 | 2564 | 2624 | 2564 | 2564 | 2564 | 2281 |
| | Molecular Weight *⁴ | | | | | | | |
| Thermoplastic | PB-2000 | 15 | 15 | — | — | — | — | — |
| resin | (Styrene 0%) | | | | | | | |
| | RICON-184 | — | — | 15 | 15 | — | 15 | 10 |
| | (Styrene 27%) | | | | | | | |
| | RICON-257 | — | — | — | — | 15 | — | — |
| | (Styrene 35%) | | | | | | | |
| Polystyrene | SEBS | 10 | — | 10 | — | — | — | 15 |
| | (Styrene 20%) | | | | | | | |
| | SEBS | — | — | — | — | — | — | — |
| | (Styrene 85%) | | | | | | | |
| | Polystyrene (Styrene100%) | — | 10 | — | 10 | 10 | 10 | 15 |
| Cross-Linking | TAIC | 10 | 10 | 10 | 10 | 10 | 10 | 10 |
| Agent | | | | | | | | |
| Flame | BT-93 | 14.6 | 14.6 | 14.6 | 14.6 | 14.6 | — | 14.6 |
| Retardant | 8010 | — | — | — | — | — | — | — |
| | DOPO-based flame retardant | — | — | — | — | — | 14.6 | — |
| | (Formula E) *⁵ | | | | | | | |
| Filler | SiO2 | 20 | 20 | 20 | 20 | 20 | 20 | 20 |
| Initiator | 1,4 Bis(tert- | 0.2 | 0.2 | 0.2 | 0.2 | 0.2 | 0.2 | 0.2 |
| | butyldioxyisopropyl) benzene | | | | | | | |
| | Vumene hydroperoxide | 0.2 | 0.2 | 0.2 | 0.2 | 0.2 | 0.2 | 0.2 |
| Glass Transition Temperature(° C.) (DMA) *⁶ | | 213 | 217 | 225 | 231 | 228 | 207 | 204 |
| Water Absorbency (%) *⁷ | | 0.03 | 0.02 | 0.02 | 0.03 | 0.03 | 0.02 | 0.01 |
| 288° C. Solder Heat Resistance (Sec) *⁸ | | >600 | >600 | >600 | >600 | >600 | >600 | >600 |
| Copper Peel Strength (lb/in) | | 7.21 | 5.68 | 5.75 | 5.68 | 5.75 | 5.95 | 7.68 |
| Rigidity (Modulus at 50° C., GPa) *⁹ | | 12.7 | 14.5 | 15.6 | 16.1 | 15.7 | 13.8 | 10.5 |
| Dielectric constant (Dk) | | 2.75 | 2.90 | 2.65 | 2.62 | 2.64 | 2.87 | 2.68 |
| Dielectic dissipation factor (Df) (×10⁻³) | | 1.7 | 1.6 | 1.6 | 1.5 | 1.5 | 1.7 | 1.6 |
| Flame Resistance (UL-94) | | V0 | V0 | V0 | V0 | V0 | V0 | V0 |
| Filling performance on 2 OZ thick copper | | no | no | no | no | no | no | no |
| circuit boards *¹⁰ | | gap | gap | gap | gap | gap | gap | gap |
| Is prepreg easily cutting? | | yes | yes | yes | yes | yes | yes | yes |
| Will the prepreg stick to your hands? | | no | no | no | no | no | no | no |
| | | Embodiment | | | | Comparative Examples | | |
| Composition (weight percentage) | | 8 | 9 | 10 | 11 | 1 | 2 | 3 |
| Thermosetting | PPE-A (ended with styrene groups) *¹ | 15 | 15 | 15 | 15 | — | 10 | 5 |
| polyphenylene | PPE-B (ended with | 15 | 15 | 15 | 15 | — | 10 | 5 |
| ether resin | acrylate groups) *² | | | | | | | |
| | PPE-C (ended with | — | — | — | — | 50 | — | — |
| | OH groups) | | | | | | | |
| | OH Value *³ | 0.02 | 0.02 | 0.01 | 0.01 | 47 | 0.02 | 0.02 |
| | Polyphenylene Ether | 2564 | 2281 | 2369 | 2369 | 2052 | 2761 | 2564 |
| | Molecular Weight *⁴ | | | | | | | |
| Thermoplastic | PB-2000 | — | — | 15 | 15 | — | — | — |
| resin | (Styrene 0%) | | | | | | | |
| | RICON-184 | 15 | 15 | — | — | — | 30 | 5 |
| | (Styrene 27%) | | | | | | | |
| | RICON-257 | — | — | — | — | — | — | — |
| | (Styrene 35%) | | | | | | | |
| Polystyrene | SEBS | — | 35 | — | — | — | — | 22.5 |
| | (Styrene 20%) | | | | | | | |
| | SEBS | — | — | 10 | 5 | — | — | — |
| | (Styrene 85%) | | | | | | | |
| | Polystyrene (Styrene100%) | 10 | — | — | 5 | — | 10 | 22.5 |
| Cross-Linking | TAIC | 10 | 10 | 10 | 10 | 10 | 5 | 5 |
| Agent | | | | | | | | |
| Flame | BT-93 | — | 14.6 | 14.6 | 14.6 | 14.6 | 14.6 | 14.6 |
| Retardant | 8010 | 14.6 | — | — | — | — | — | — |
| | DOPO-based flame retardant | — | — | — | — | — | — | — |
| | (Formula E) *⁵ | | | | | | | |
| Filler | SiO2 | 20 | 20 | 20 | 20 | 20 | 20 | 20 |
| Initiator | 1,4 Bis(tert- | 0.2 | 0.2 | 0.2 | 0.2 | 0.2 | 0.2 | 0.2 |
| | butyldioxyisopropyl) benzene | | | | | | | |
| | Vumene hydroperoxide | 0.2 | 0.2 | 0.2 | 0.2 | 0.2 | 0.2 | 0.2 |

| | | | | | | | |
|---|---|---|---|---|---|---|---|
| Glass Transition Temperature (° C.) (DMA) *⁶ | 210 | 212 | 213 | 213 | 213 | 202 | 186 |
| Water Absorbency (%) *⁷ | 0.02 | 0.02 | 0.02 | 0.02 | 0.02 | 0.02 | 0.02 |
| 288° C. Solder Heat Resistance (Sec) *⁸ | >600 | >600 | >600 | >600 | 389 | 464 | 385 |
| Copper Peel Strength (lb/in) | 5.75 | 5.86 | 7.25 | 7.26 | 7.25 | 3.89 | 5.89 |
| Rigidity (Modulus at 50° C., GPa) *⁹ | 13.8 | 14.6 | 12.8 | 12.9 | 12.8 | 9.2 | 8.8 |
| Dielectric constant (Dk) | 2.65 | 2.63 | 2.74 | 2.73 | 3.41 | 2.88 | 3.12 |
| Dielectic dissipation factor (Df) (×10⁻³) | 1.6 | 1.6 | 1.6 | 1.5 | 3.7 | 1.5 | 2.5 |
| Flame Resistance (UL-94) | V0 | V0 | V0 | V0 | V0 | NG | NG |
| Filling performance on 2 OZ thick copper | no | no | no | no | no | has | has |
| circuit boards *¹⁰ | gap | gap | gap | gap | gap | gap | gap |
| Is prepreg easily cutting? | yes | yes | yes | yes | yes | no | yes |
| Will the prepreg stick to your hands? | no | no | no | no | no | yes | slight |

Remark:
* 1. The styrene-ended polyphenylene ether resin has the following chemical structure. 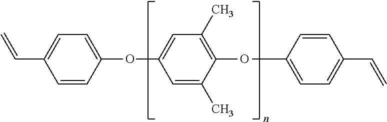
*2. The acrylate-ended polyphenylene ether resin has the following chemical structure. 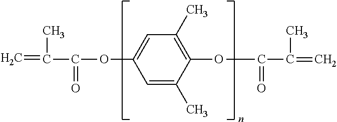
*3. The OH value is measured by preparing a 25 vol. % acetic anhydride solution in pyridine as the acetylation reagent, precisely weighting the sample, mixing it with 5 mL of the macetylation reagent, heating to full dissolution, adding phenolphthalein as the indicator, and standardizing using 0.5 N potassium hydroxide solution in ethanol.
*4. Molecular weight of the polyphenylene ether resin is determined by dissolving a given amount of the polyphenylene ether resin in THF solvent to prepare a 1% solution, heating the solution to clearness, performing GPC (gel permeation chromatography) analysis and calculating the area of the characteristic peak.
*5. The DOPO-based flame retardant has the following Formula E 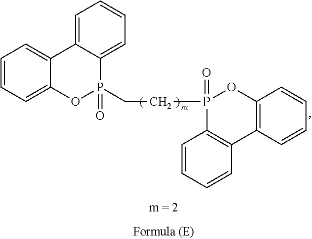
*6. Glass transition temperature (° C.) is measured with a dynamic mechanical analyzer (DMA).
*7. Water absorbency (%) is determined by heating test pieces in a pressure pot at 120° C. and 2 atm for 120 minutes and calculating the weight difference before and after the heating.
*8. 288° C. soldering heat resistance (sec) is measured as the time taken before delamination occurred by heating test pieces in a pressure pot at 120° C. and 2 atm for 120 minutes an and dipping them into a 288° C. soldering machine; and the symbol of >600 is meant the time for 288° C. soldering heat resistance greater than 600 sec.
*9. Rigidity is measured with a dynamic mechanical analyzer (DMA) and expressed in the G′ value (storage modulus, GPa) at 50° C.
*10. Six sheets of 1080-Specification electronic glass cloth having a resin content (RC) of 70% were laminated with thick copper circuit boards. The laminates were sliced to see whether the gaps were fully filled.

What is claimed is:

1. A thermosetting resin composition, comprising the following components, and based on the total solid content of the thermosetting resin composition, the sum of the following components is 100 wt %:
(a) a thermosetting polyphenylene ether resin, taking up 10-30 wt %; including a styrene-ended polyphenylene ether resin of Formula (A) as follows and an acrylate-ended polyphenylene ether resin of Formula (B) as follows, and the weight ratio of the styrene-containing polyphenylene ether resin to the acrylate-containing polyphenylene ether resin ranged from 0.5 to 1.5; 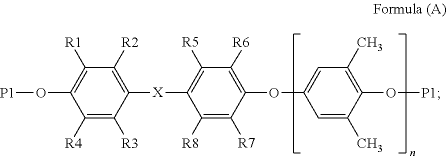
where R1-R8 may be allyl or hydryl or C1-C6 alkyl, or one or more selected from the foregoing group;
X may be O (oxygen atoms), or 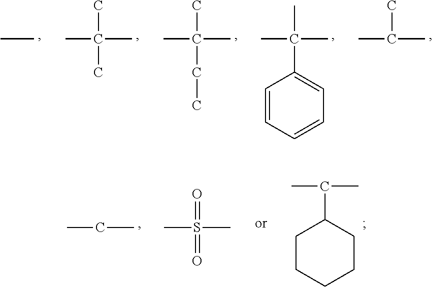
where P1 is a styrene group, n is an integer in a range of 1-99; 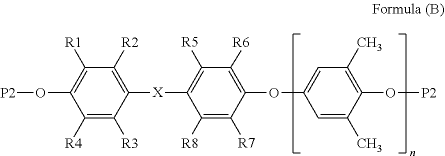
where R1-R8 may be allyl or hydryl or C1-C6 alkyl, or one or more selected from the foregoing group;
X may be: O (oxygen atoms), or 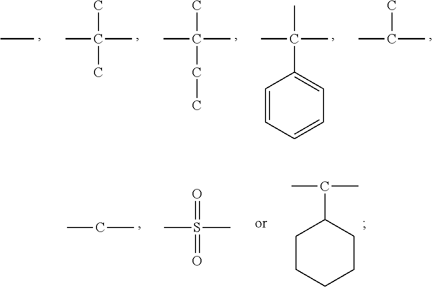
P2 is 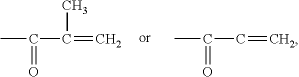
n is an integer in a range of 1-99;
(b) a thermosetting polybutadiene resin, taking up 10-30 wt %, and being one or more selected from a polybutadiene resin and a butadiene-styrene copolymer, wherein the polybutadiene resin has a number-average molecular weight (Mn) of smaller than 5,000, and the butadiene-styrene copolymer has a styrene ratio of 10-35%;
(c) a thermoplastic resin, taking up 10-30 wt %, and being one or more selected from polystyrene resin (PS), polystyrene-poly(ethylene-ethylene/propylene)-polystyrene resin (SEEPS), polystyrene-poly(ethylene-propylene)-polystyrene resin (SEPS), and polystyrene-poly(ethylene-butylene)-polystyrene resin (SEBS);
(d) inorganic powder, taking up 20-40 wt %;
(e) a flame retardant, taking up 5-25 wt %;
(f) a cross-linking agent, taking up 5-20 wt %, and being one or more selected from triallyl cyanurate (TAC); triallyl isocyanurate (TAIC); trimethallyl isocyanurate (TMAIC); diallyl phthalate; divinylbenzene; and 1,2,4-Triallyl trimellitate;
(g) a compound cross-linking initiator, being an organic peroxide containing more than 5% of reactive oxygen, taking up 0.1-3 wt %, and being one or more selected from dicumyl peroxide; bis(tert-butyldioxyisopropyl)benzene; 2,5 -dimethyl-2,5-di(tert-butylperoxy)hexane; di-tert-pentyl peroxide; di-tert-butyl peroxide and cumene hydroperoxide.

2. The thermosetting resin composition of claim 1, wherein the thermosetting polyphenylene ether resin has an OH value of smaller than 1.0 mgKOH/g.

3. The thermosetting resin composition of claim 1, wherein the weight ratio of the styrene-containing polyphenylene ether resin to the acrylate-containing polyphenylene ether resin ranged from 0.75 to 1.25.

4. The thermosetting resin composition of claim 1, wherein the thermoplastic resin contains the styrene-containing copolymer having styrene groups in a proportion of 10-85%.

5. The thermosetting resin composition of claim 1, wherein the flame retardant is a brominated flame retardant selected from ethylene bistetrabromophthalimide flame retardant, tetradecabromodiphenoxy benzene flame retardant, ethane-1,2-bis(pentabromophenyl) flame retardant or decabromo diphenoxy oxide flame retardant.

6. The thermosetting resin composition of claim 1, wherein the flame retardant is a phosphorus flame retardant selected from phosphate-based, phosphazene-based or DOPO-based flame retardant.

7. The thermosetting resin composition of claim 6, wherein the flame retardant is an Al-containing hypophosphites of Formula F as follows:

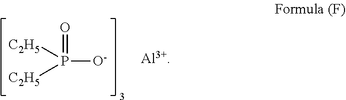

8. The thermosetting resin composition of claim 1, wherein the DOPO-based flame retardant is selected from DOPO with the following Formula C, DOPO-HQ with the following Formula D, or dual-DOPO derivatives with the following Formula E.

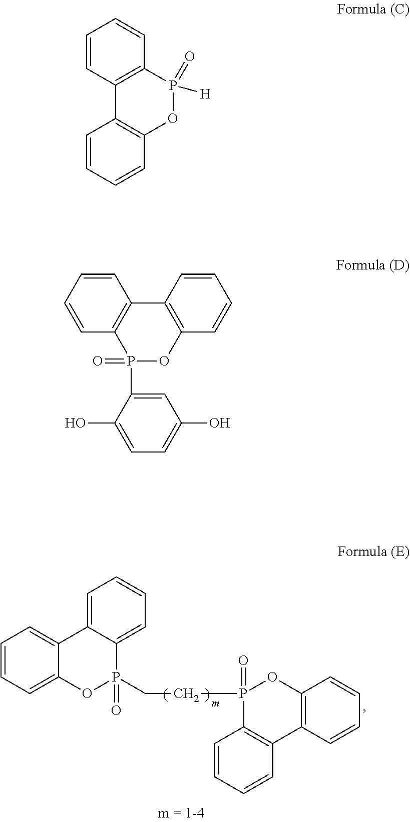

9. The thermosetting resin composition of claim 1, wherein the compound cross-linking initiator is a mixture of dicumyl peroxide and bis(tert-butyldioxyisopropyl)benzene.

10. The thermosetting resin composition of claim 1, wherein the compound cross-linking initiator is an organic peroxide that contains more than 5% reactive oxygen.

11. A printed circuit board, comprising an insulating layer made of the thermosetting resin composition according to claim 1.
